(19) United States
(12) Patent Application Publication
(10) Pub. No.: US 2024/0313048 A1
(43) Pub. Date: Sep. 19, 2024

(54) STRUCTURE AND FORMATION METHOD OF SEMICONDUCTOR DEVICE WITH SEMICONDUCTOR NANOSTRUCTURE

(71) Applicant: Taiwan Semiconductor Manufacturing Company, Ltd., Hsinchu (TW)

(72) Inventors: Kuo-Cheng CHIANG, Zhubei City (TW); Guan-Lin CHEN, Baoshan Township (TW); Shi-Ning JU, Hsinchu City (TW); Jung-Chien CHENG, Tainan City (TW); Chih-Hao WANG, Baoshan Township (TW)

(73) Assignee: Taiwan Semiconductor Manufacturing Company, Ltd., Hsinchu (TW)

(21) Appl. No.: 18/185,232

(22) Filed: Mar. 16, 2023

(51) Int. Cl. H01L 29/06; H01L 21/8238; H01L 27/092; H01L 29/423; H01L 29/66; H01L 29/775; H01L 29/786

(52) U.S. Cl. CPC H01L 29/0673; H01L 21/823807; H01L 21/823864; H01L 21/823878; H01L 27/092; H01L 29/42392; H01L 29/66439; H01L 29/775; H01L 29/78696

(57) ABSTRACT

A semiconductor device structure and a formation method are provided. The method includes forming a channel structure over a substrate and forming a protective spacer over sidewalls of the channel structure. The method also includes forming an insulating wall adjacent to an end of the channel structure. The method further includes removing the protective spacer to expose the channel structure. In addition, the method includes forming a metal gate stack surrounding an intermediate portion of the channel structure.

### BACKGROUND

The semiconductor integrated circuit (IC) industry has experienced rapid growth. Technological advances in IC materials and design have produced generations of ICs. Each generation has smaller and more complex circuits than the previous generation.

Over the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, these advances have increased the complexity of processing and manufacturing ICs. Since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1Y are perspective views of various stages of a process for forming a portion of a semiconductor device structure, in accordance with some embodiments.

FIGS. 1K-1 to 1R-1 are cross-sectional views of a process for forming a portion of a semiconductor device structure, in accordance with some embodiments.

FIG. 2 is a cross-sectional view of a portion of a semiconductor device structure, in accordance with some embodiments.

FIG. 3 is a cross-sectional view of a portion of a semiconductor device structure, in accordance with some embodiments.

FIG. 4 is a cross-sectional view of a portion of a semiconductor device structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the disclosure may relate to FinFET structure having fins and/or gate all around (GAA) transistor structures (which include channel layers suspended over a substrate, where the channel layers are fabricated from semiconductor layers stacks (i.e., fins)). The fins may be patterned using any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. However, the fins may be formed using one or more other applicable processes.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

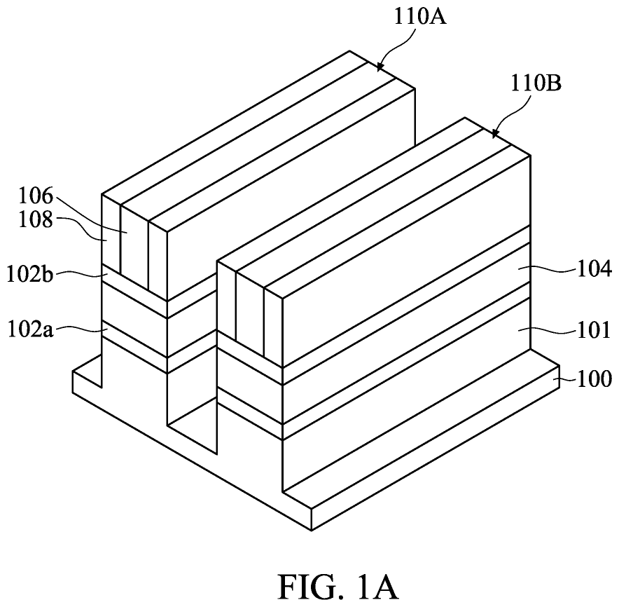

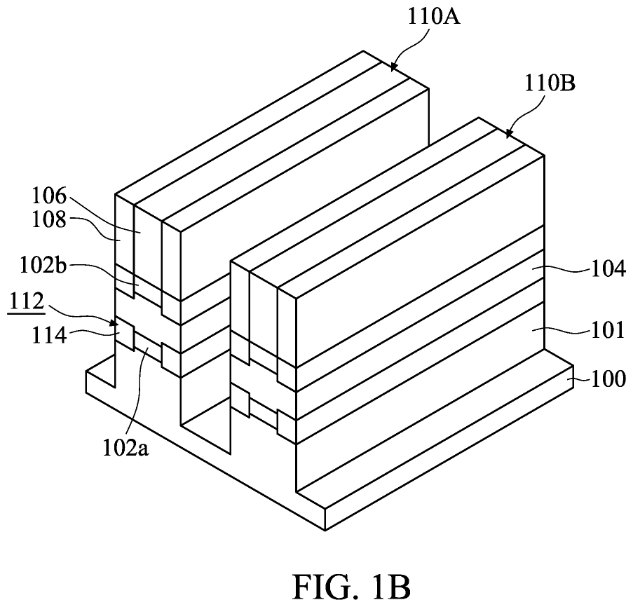

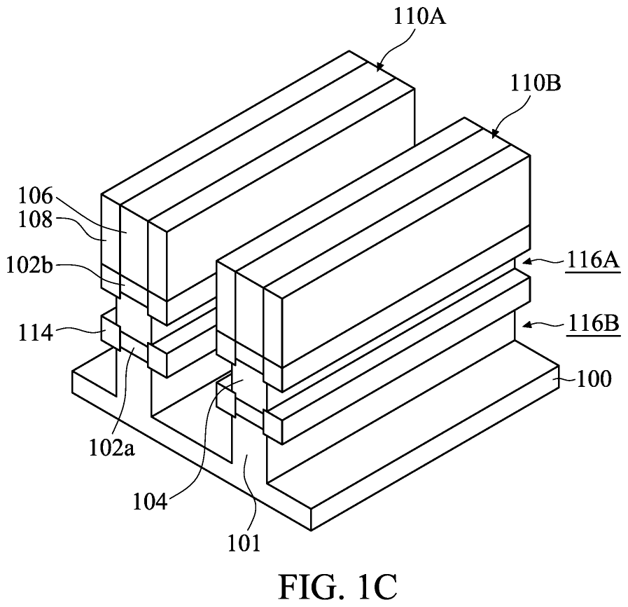

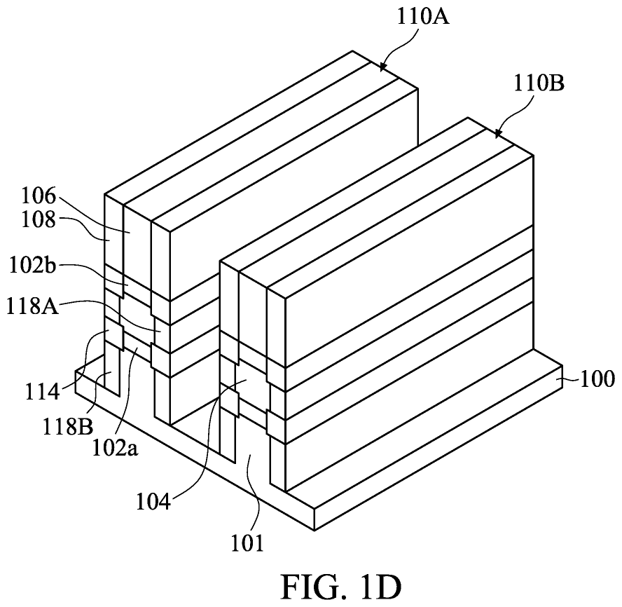

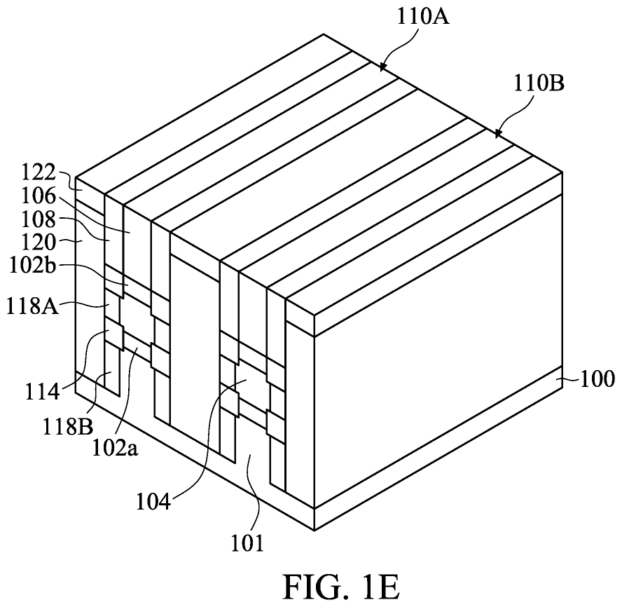

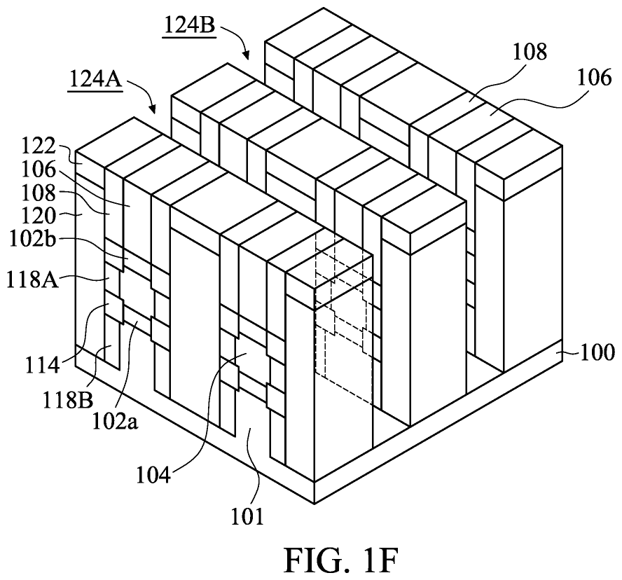

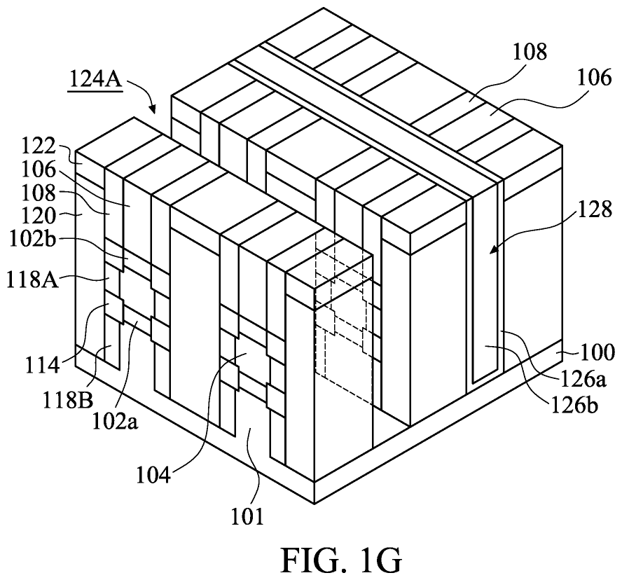

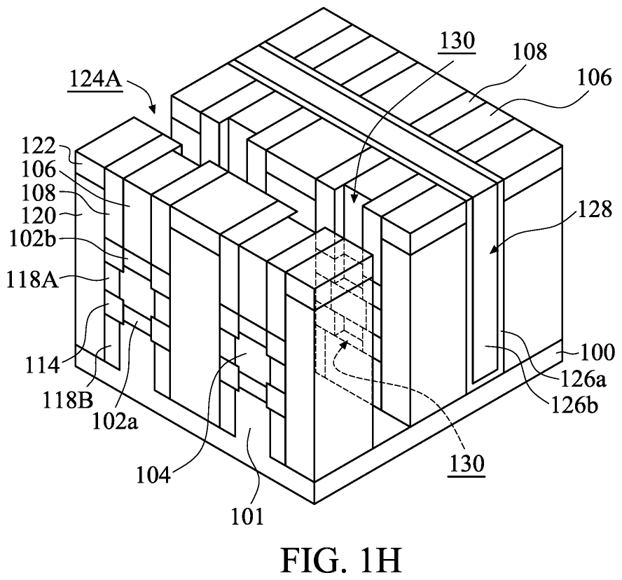

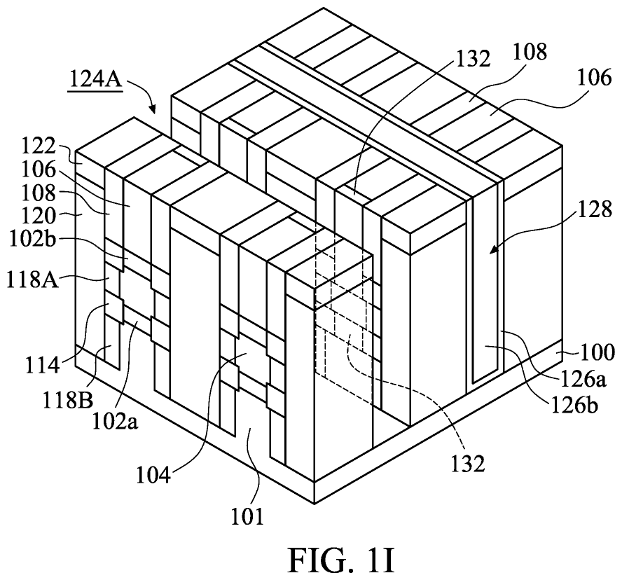

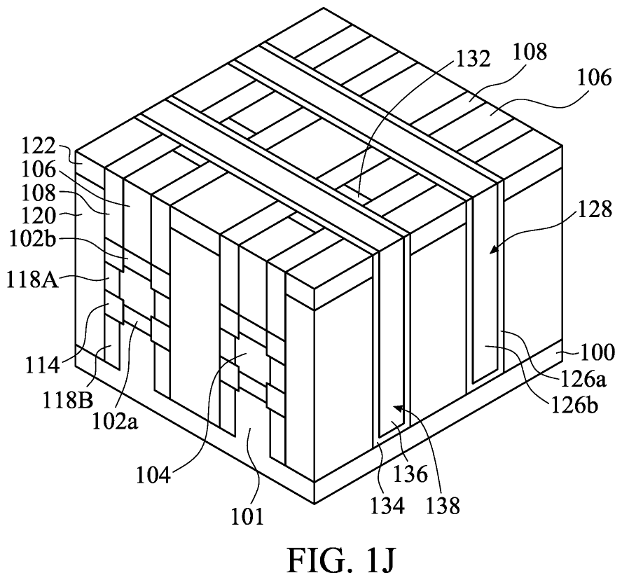

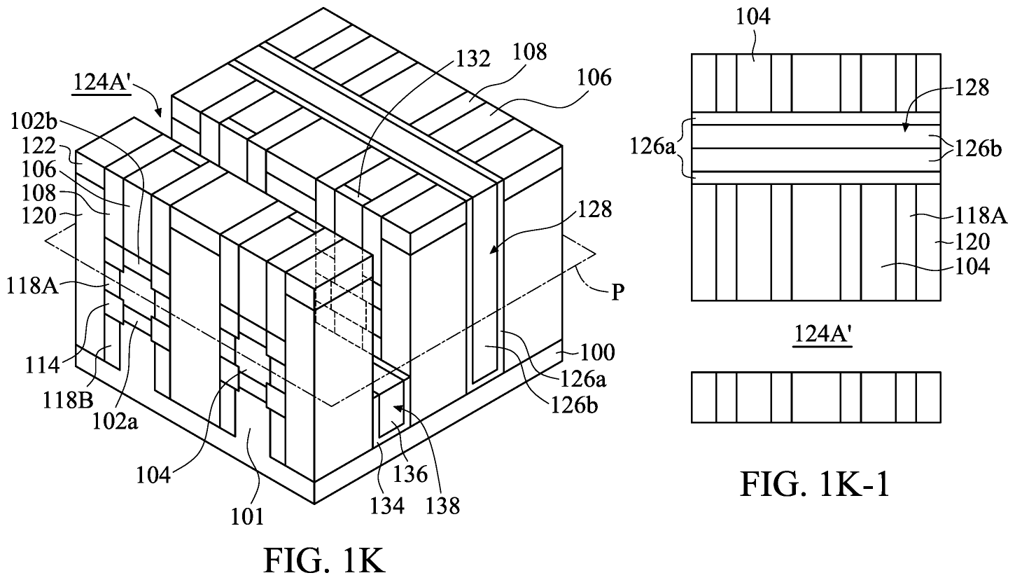

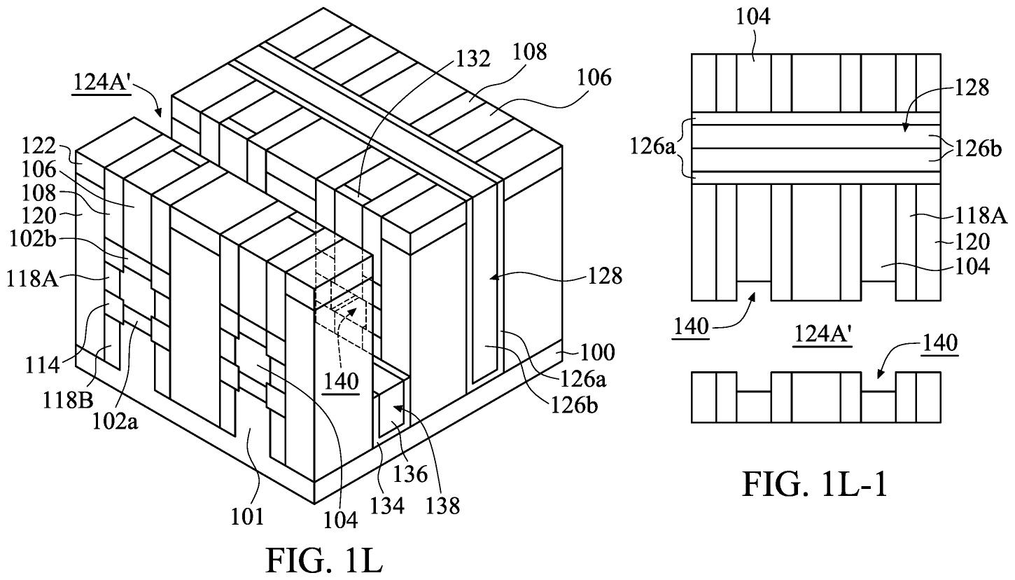

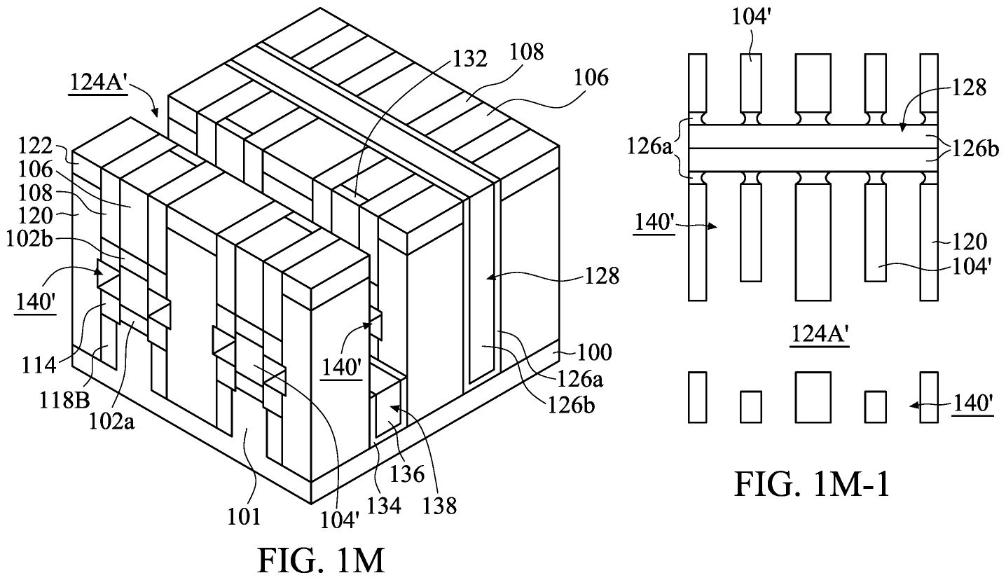

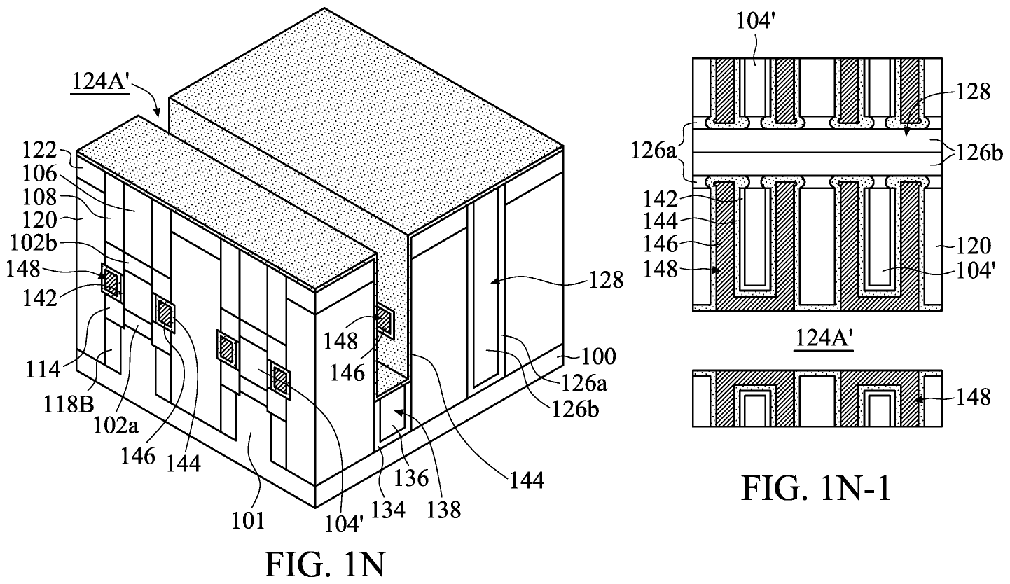

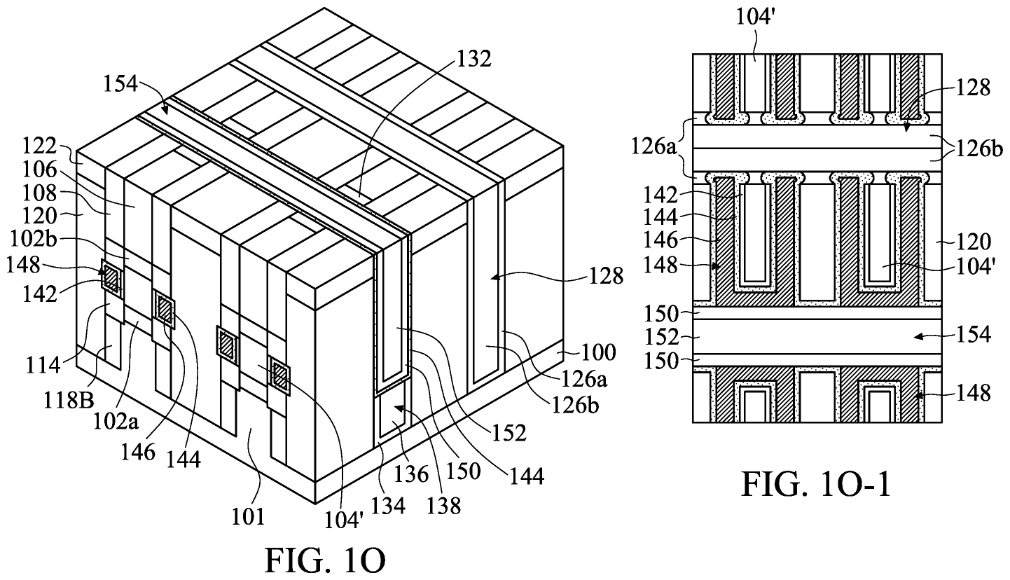

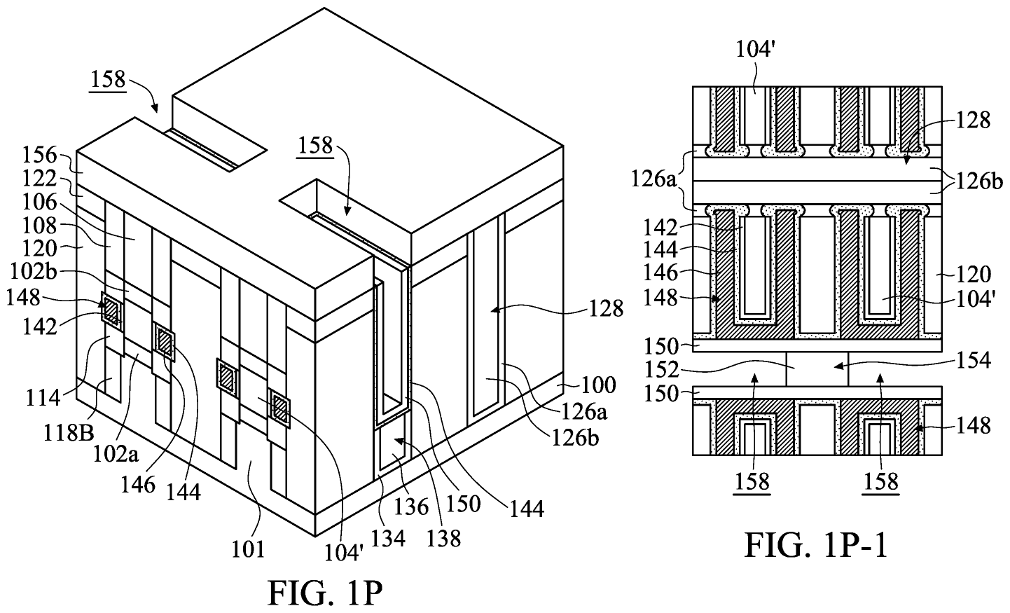

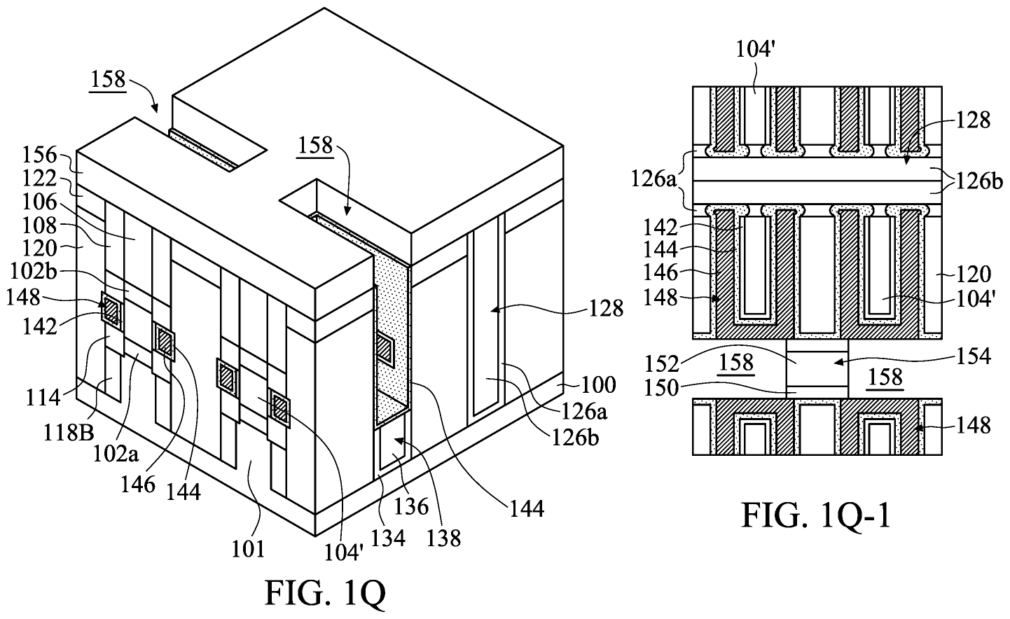

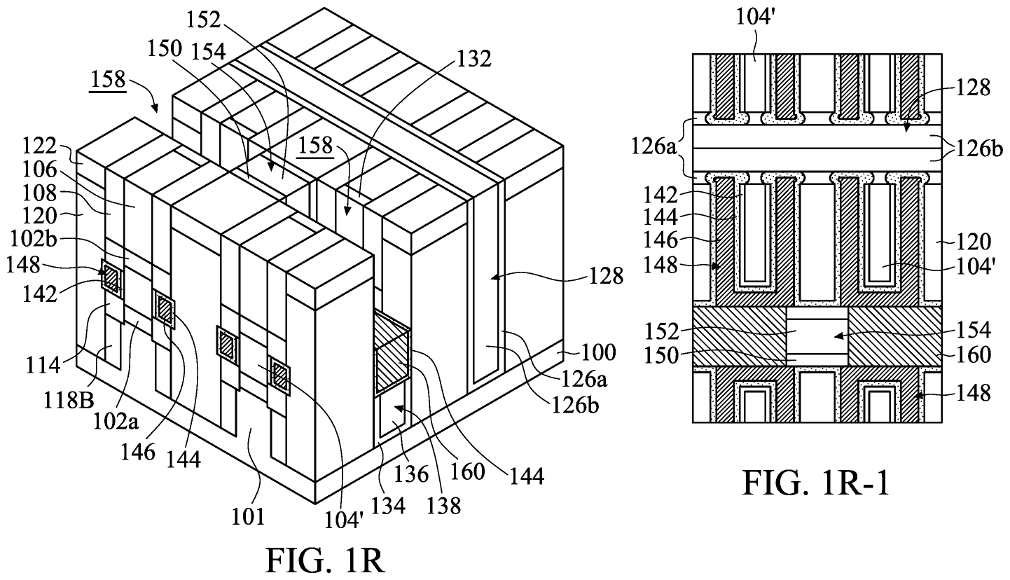

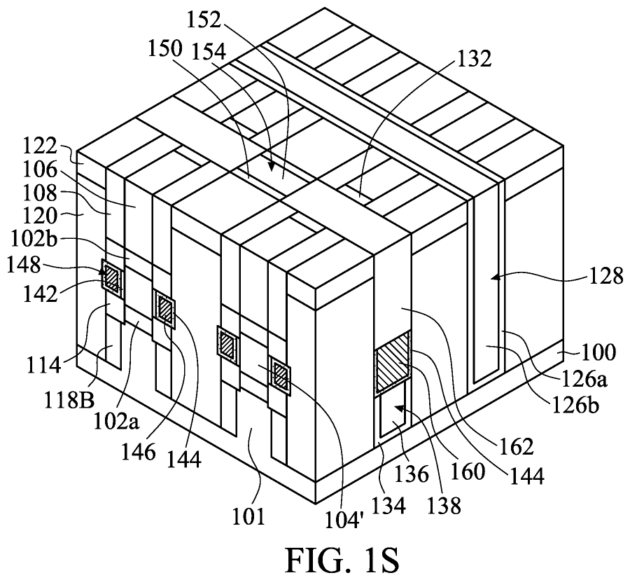

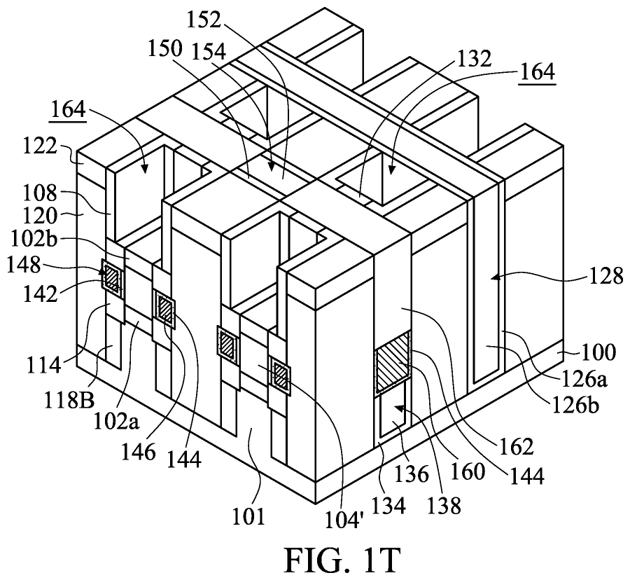

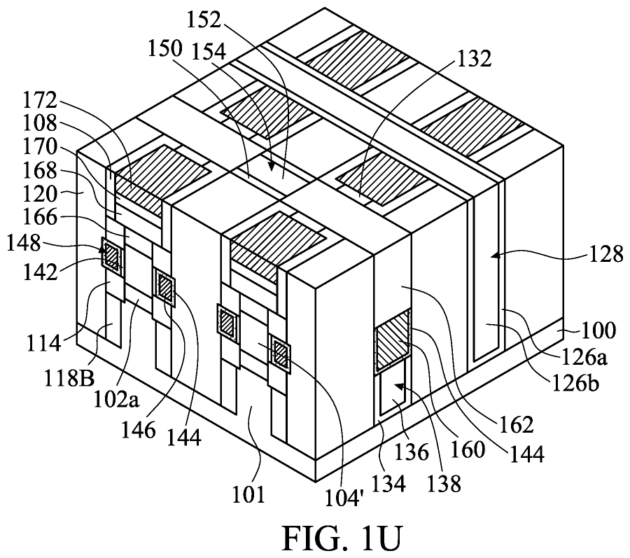

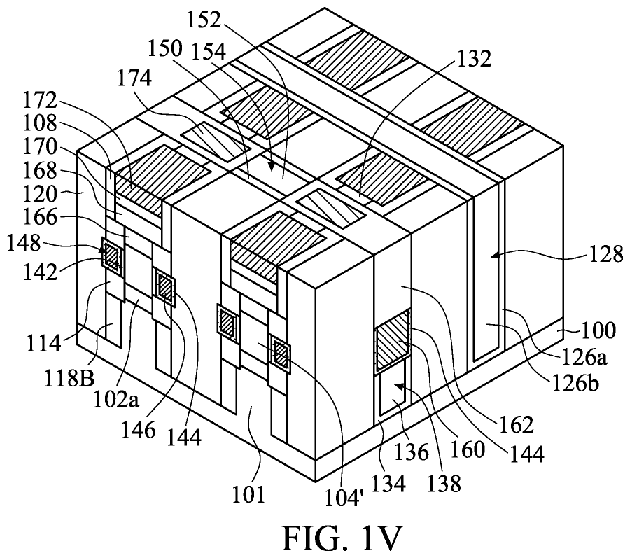

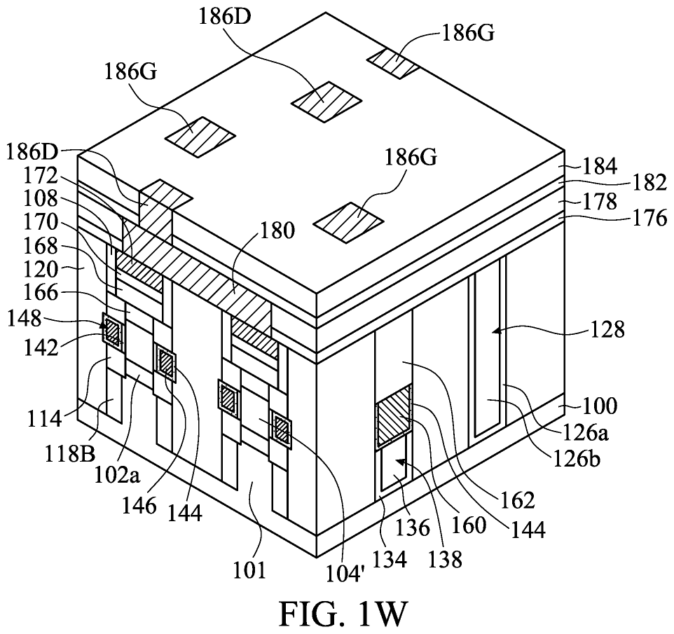

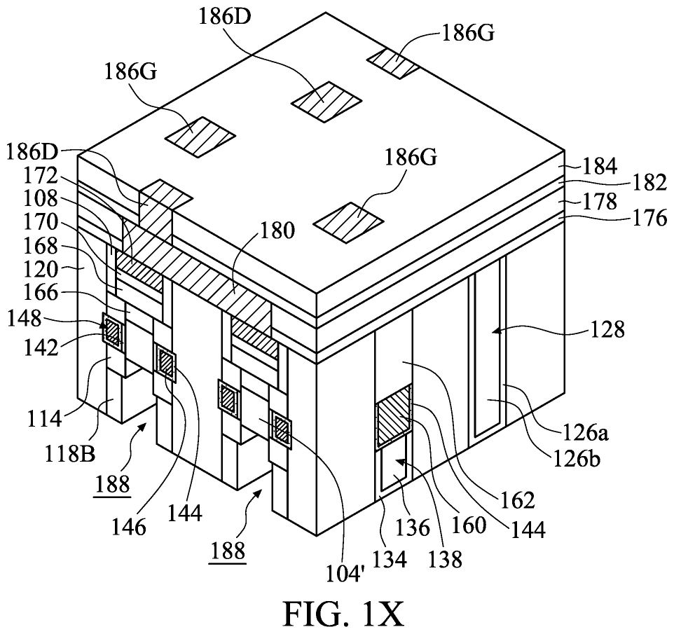

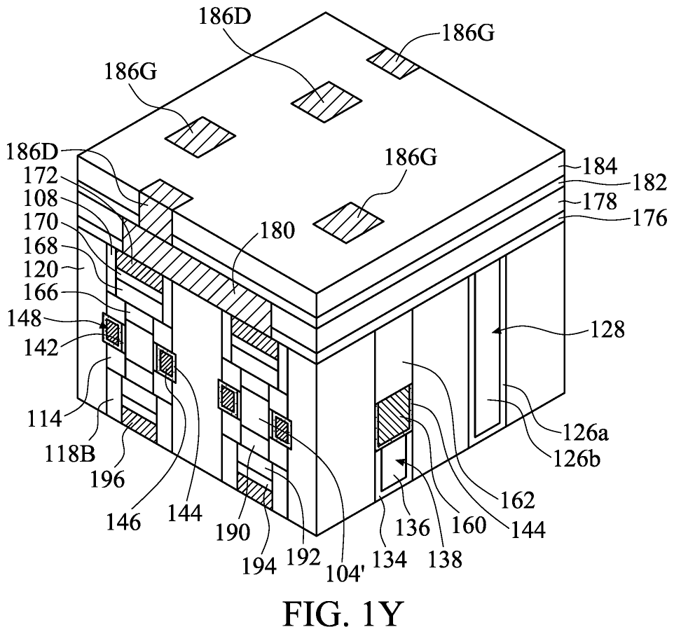

FIGS. 1A-1Y are perspective views of various stages of a process for forming a portion of a semiconductor device structure, in accordance with some embodiments. As shown in FIG. 1A, a semiconductor substrate 100 is received or provided. In some embodiments, the semiconductor substrate 100 is a bulk semiconductor substrate, such as a semiconductor wafer. The semiconductor substrate 100 may include silicon or other elementary semiconductor materials such as germanium. The semiconductor substrate 100 may be un-doped or doped (e.g., p-type, n-type, or a combination thereof). In some embodiments, the semiconductor substrate 100 includes an epitaxially grown semiconductor layer on a dielectric layer. The epitaxially grown semiconductor layer may be made of silicon germanium, silicon, germanium, one or more other suitable materials, or a combination thereof.

In some other embodiments, the semiconductor substrate 100 includes a compound semiconductor. For example, the compound semiconductor includes one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

In some embodiments, the semiconductor substrate 100 is an active layer of a semiconductor-on-insulator (SOI) substrate. The SOI substrate may be fabricated using a separation by implantation of oxygen (SIMOX) process, a wafer bonding process, another applicable method, or a combination thereof. In some other embodiments, the semiconductor substrate 100 includes a multi-layered structure. For example, the semiconductor substrate 100 includes a silicon-germanium layer formed on a bulk silicon layer.

In some embodiments, a semiconductor stack having multiple semiconductor layers is formed over the semiconductor substrate 100. In some embodiments, the semiconductor stack includes multiple semiconductor layers 102a and 102b. The semiconductor stack also includes a semiconductor layer 104. In some embodiments, the semiconductor layer 104 is between the semiconductor layers 102a and 102b.

In some embodiments, the semiconductor layers 102a and 102b function as sacrificial layers that will be removed in a subsequent process. The semiconductor layer 104 may function as channel layer that is used for forming multiple channel structures of one or more transistors.

In some embodiments, the semiconductor layer 104 is used to form channel structures. The semiconductor layer 104 may be made of a material that is different than that of the semiconductor layers 102a and 102b. In some embodiments, the semiconductor layer 104 is made of or include silicon, germanium, one or more other suitable materials, or a combination thereof. In some embodiments, the semiconductor layers 102a and 102b are made of or include silicon germanium. In some other embodiments, the semiconductor layer 104 is made of silicon germanium, and the semiconductor layers 102a and 102b are made of silicon germanium with different atomic concentration of germanium than that of the semiconductor layer 104. As a result, different etching selectivity and/or different oxidation rates during subsequent processing may be achieved between the semiconductor layers 102a-102b and the semiconductor layer 104.

The present disclosure contemplates that the semiconductor layers 102a-102b and the semiconductor layer 104 include any combination of semiconductor materials that can provide desired etching selectivity, desired oxidation rate differences, and/or desired performance characteristics (e.g., materials that maximize current flow).

In some embodiments, the semiconductor layers 102a, 102b, and 104 are formed using multiple epitaxial growth operations. Each of the semiconductor layers 102a, 102b, and 104 may be formed using a selective epitaxial growth (SEG) process, a chemical vapor deposition (CVD) process (e.g., a vapor-phase epitaxy (VPE) process, a low-pressure chemical vapor deposition (LPCVD) process, and/or an ultra-high vacuum CVD (UHV-CVD) process), a molecular beam epitaxy process, one or more other applicable processes, or a combination thereof.

In some embodiments, the semiconductor layers 102a, 102b, and 104 are grown in-situ in the same process chamber. In some embodiments, the growth of the semiconductor layers 102a, 102b, and 104 are alternately and sequentially performed in the same process chamber to complete the formation of the semiconductor stack. In some embodiments, the vacuum of the process chamber is not broken before the epitaxial growth of the semiconductor stack is accomplished.

Afterwards, hard mask elements are formed over the semiconductor stack to assist in a subsequent patterning of the semiconductor stack. Each of the hard mask elements may include a mask layer 106 and mask spacers 108. The mask layer 106 and the mask spacers 108 may be made of different materials, so as to provide desired etching selectivity. In some embodiments, the mask layer 106 is made of an oxide material such as silicon oxide, and the mask spacers 108 is made of a nitride material such as silicon nitride.

As shown in FIG. 1A, the semiconductor stack is patterned to form multiple fin structures including fin structures 110A and 110B, in accordance with some embodiments. One or more photolithography processes and one or more etching processes are used to partially remove the semiconductor stack, so as to form the fin structures 110A-110B, as shown in FIG. 1A.

The semiconductor stack may be patterned to form the fin structures 110A-110B by any suitable method. For example, the fin structures 110A-110B may be formed using one or more photolithography processes, including double-patterning or multi-patterning processes. Double-patterning or multi-patterning processes may combine photolithography and self-aligned processes, allowing patterns to be created that have, for example, pitches smaller than what is otherwise obtainable using a single, direct photolithography process.

Each of the fin structures 110A-110B may include portions of the semiconductor layers 102a, 102b, and 104 and a semiconductor fin 101, as shown in FIG. 1A. The semiconductor substrate 100 may also be partially removed during the etching process that forms the fin structures 110A-110B. Protruding portions of the semiconductor substrate 100 that remain form the semiconductor fins 101, as shown in FIG. 1A.

As shown in FIG. 1B, the sacrificial layers 102a and 102b are partially removed, in accordance with some embodiments. As a result, the edges of the sacrificial layers 102a and 102b retreat from the edges of the semiconductor layer 104, so as to form multiple recesses 112 that are used for containing inner spacers 114 that will be formed later. In some embodiments, the semiconductor layers 102a and 102b are laterally etched. The semiconductor layers 102a and 102b may be laterally etched using a wet etching process, a dry etching process, or a combination thereof. In some other embodiments, the semiconductor layers 102a and 102b are partially oxidized before being laterally etched.

In some embodiments, an insulating layer is deposited to overfill the recesses 112. In some embodiments, the insulating layer is a single layer. In some other embodiments, the insulating layer includes multiple sub-layers. Some of the sub-layers may be made of different materials and/or contain different compositions.

The insulating layer may be made of or include carbon-containing silicon nitride (SiCN), carbon-containing silicon oxynitride (SiOCN), carbon-containing silicon oxide (SiOC), silicon oxide, silicon nitride, one or more other suitable materials, or a combination thereof. The insulating layer may be deposited using a CVD process, an ALD process, another applicable process, or a combination thereof.

Afterwards, an etching process is used to partially remove the insulating layer, in accordance with some embodiments. The portions of the insulating layer outside of the recesses 112 may be removed. The remaining portions of the insulating layer form the inner spacers 114, as shown in FIG. 1B. The etching process may include a dry etching process, a wet etching process, or a combination thereof.

As shown in FIG. 1C, the semiconductor layer 104 and the semiconductor fins 101 are partially removed, in accordance with some embodiments. As a result, the edges of the semiconductor layer 104 and the semiconductor fins 101 retreat from the edges of the inner spacers 114, so as to form multiple recesses 116A and 116B that are used for containing protective spacers that will be formed later. In some embodiments, the semiconductor layer 104 and the semiconductor fins 101 are laterally etched. The semiconductor layer 104 and the semiconductor fins 101 may be laterally etched using a wet etching process, a dry etching process, or a combination thereof. In some other embodiments, the semiconductor layer 104 and the semiconductor fins 101 are partially oxidized before being laterally etched.

As shown in FIG. 1D, protective spacers 118A and 118B are respectively formed in the recesses 116A and 116B, in accordance with some embodiments. In some embodiments, a spacer layer is deposited to overfill the recesses 116A and 116B. In some embodiments, the spacer layer is a single layer. In some other embodiments, the spacer layer includes multiple sub-layers. Some of the sub-layers may be made of different materials and/or contain different compositions.

The spacer layer may be made of or include carbon-containing silicon nitride (SiCN), carbon-containing silicon oxynitride (SiOCN), carbon-containing silicon oxide (SiOC), silicon oxide, silicon nitride, one or more other suitable materials, or a combination thereof. In some other embodiments, the spacer layer is made of or includes a semiconductor material such as silicon germanium. The spacer layer may be deposited using a CVD process, an ALD process, another applicable process, or a combination thereof.

Afterwards, an etching process is used to partially remove the spacer layer, in accordance with some embodiments. The portions of the spacer layer outside of the recesses 116 and 116B may be removed. The remaining portions of the spacer layer form the protective spacers 118A and 118B, as shown in FIG. 1D. The etching process may include a dry etching process, a wet etching process, or a combination thereof.

As shown in FIG. 1E, an isolation feature 120 is formed to laterally surround the fin structures 110A and 110B, in accordance with some embodiments. In some embodiments, a dielectric layer is deposited over the fin structures 110A-110B and the semiconductor substrate 100. The dielectric layer may be a single layer or include multiple sub-layers. The dielectric layer may be made of or include silicon oxide, silicon oxynitride, borosilicate glass (BSG), phosphoric silicate glass (PSG), borophosphosilicate glass (BPSG), fluorinated silicate glass (FSG), low-k material, porous dielectric material, one or more other suitable materials, or a combination thereof. The dielectric layer may be deposited using a flowable chemical vapor deposition (FCVD) process, an atomic layer deposition (ALD) process, a chemical vapor deposition (CVD) process, one or more other applicable processes, or a combination thereof.

Afterwards, a planarization process is used to partially remove the dielectric layer. As a result, the tops of the mask layers 106 and mask spacers 108 are exposed. The planarization process may include a chemical mechanical polishing (CMP) process, a grinding process, an etching process, another applicable process, or a combination thereof. Afterwards, the dielectric layer is etched back to form recesses. The remaining portions of the dielectric layer form the isolation feature 120. Mask elements 122 are then formed in the recesses, as shown in FIG. 1E.

In some embodiments, a mask layer is deposited over the isolation feature 120 to overfill the recesses above the isolation feature 120. The mask layer may be made of or include silicon nitride, silicon oxynitride, carbon-containing silicon oxynitride, another suitable material, or a combination thereof. The mask layer may be deposited using a CVD process, an ALD process, another applicable process, or a combination thereof. Afterwards, a planarization process is used to partially remove the mask layer. As a result, the remaining portions of the mask layer form the mask elements 122, as shown in FIG. 1E. The planarization process may include a chemical mechanical polishing (CMP) process, a grinding process, an etching process, another applicable process, or a combination thereof.

As shown in FIG. 1F, the fin structures 110A and 110B, the mask elements 122, and the isolation feature 120 are partially removed, in accordance with some embodiments. As a result, multiple trenches including trenches 124A and 124B are formed. One or more photolithography processes and one or more etching processes may be used to form the trenches 124A and 124B. The trenches 124A and 124B may divide the semiconductor layer 104 in the fin structures 110A and 110B into multiple parts. Each part of the semiconductor layer 104 may function as a channel structure.

As shown in FIG. 1G, an insulating wall 128 is formed in the trench 124B, in accordance with some embodiments. In some embodiments, the insulating wall 128 includes a single insulating layer. In some other embodiments, the insulating wall 128 includes multiple sub-layers. In some embodiments, the insulating wall 128 includes a first insulating layer 126a and a second insulating layer 126b. In some embodiments, the first insulating layer 126a surrounds the second insulating layer 126b. In some embodiments, the first insulating layer 126a and the second insulating layer 126b are made of different materials, so as to provide desired etching selectivity. The first insulating layer 126a may have a thickness that is within a range from about 2 nm to about 5 nm. The second insulating layer 126b may have a thickness that is within a range from about 5 nm to about 25 nm.

In some embodiments, a first insulating material layer and a second insulating material layer are sequentially deposited to overfill the trenches 124A and 124B. The first insulating material layer may be made of or include silicon oxide, silicon nitride, carbon-containing silicon oxide, carbon-containing silicon nitride, carbon-containing silicon oxynitride, another suitable material, or a combination thereof. The second insulating material layer may be made of or include silicon nitride, carbon-containing silicon oxide, carbon-containing silicon nitride, carbon-containing silicon oxynitride, another suitable material, or a combination thereof. The first insulating material layer and the second insulating material layer may be deposited using a CVD process, an ALD process, a flowable chemical vapor deposition (FCVD) process, another applicable process, or a combination thereof.

Afterwards, a planarization process is used to remove the portions of the first insulating material layer and the second insulating material layer that are outside of the trenches 124A and 124B. The planarization process may be a CMP process. Then, one or more photolithography processes and one or more etching processes are used to remove the portions of the first insulating material layer and the second insulating material layer that are originally within the trench 124A. As a result, the remaining portion of the first insulating material layer that is within the trench 124B forms the first insulating layer 126a of the insulating wall 128. The remaining portion of the second insulating material layer that is within the trench 124B forms the second insulating layer 126b of the insulating wall 128.

In the embodiments mentioned above, the formation of the insulating wall 128 involves a planarization process. However, embodiments of the disclosure are not limited thereto. Many variations and/or modifications can be made to embodiments of the disclosure. In some other embodiments, the formation of the insulating wall 128 does not involve a planarization process.

In some embodiments, after the formation of the first insulating material layer, a patterning process is used to remove the portion of the first insulating material layer that is outside of the trench 124B. The remaining portion of the first insulating material layer that is within the trench 124B forms the first insulating layer 126a of the insulating wall 128. Due to the occupation of the first insulating layer 126a, the trench 124B becomes narrower.

Afterwards, the second insulating material layer is deposited to slightly overfill the trench 124B. Since the trench 124B has become narrower, the second insulating material layer would only overfill the trench 124B while the trench 124A is only partially filled with the trench 124A. Then, an etching process is used to remove the portions of the second insulating material that are outside of the trench 128B. As a result, the second insulating material layer within the trench 124A is removed. The remaining portion of the second insulating material layer that is within the trench 124B forms the second insulating layer 126b of the insulating wall 128.

As shown in FIG. 1H, the mask layer 108 and the sacrificial layers 102a-102b are laterally etched, in accordance with some embodiments. As a result, multiple recesses 130 are formed. The recesses 130 may be used to contain insulating spacers that will be formed later.

As shown in FIG. 1I, insulating spacers 132 are formed in the recesses 130, in accordance with some embodiments. The insulating spacers 132 may help to electrically isolate source/drain structures from metal gate stacks that will be formed later. The insulating spacers 132 may be made of or include silicon nitride, silicon oxynitride, carbon-containing silicon oxide, carbon-containing silicon nitride, carbon-containing silicon oxynitride, another suitable material, or a combination thereof.

In some embodiments, an insulating layer is deposited to overfill the recesses 130. In some embodiments, the insulating layer is a single layer. In some other embodiments, the insulating layer includes multiple sub-layers. Some of the sub-layers may be made of different materials and/or contain different compositions. The insulating layer may be deposited using a CVD process, an ALD process, another applicable process, or a combination thereof.

Afterwards, an etching process is used to partially remove the insulating layer, in accordance with some embodiments. The portions of the insulating layer outside of the recesses 130 may be removed. As a result, the remaining portions of the insulating layer form the insulating spacers 132, as shown in FIG. 1I. The etching process may include a dry etching process, a wet etching process, or a combination thereof.

As shown in FIG. 1J, an isolation structure 138 is formed in the trench 124A, in accordance with some embodiments. The isolation structure 138 is between multiple parts of the semiconductor layer 104 that will function as channel structures. In some embodiments, the isolation structure 138 includes a first isolation layer 134 and a second isolation layer 136. The first isolation layer 134 may be made of or include silicon nitride, silicon oxynitride, another suitable material, or a combination thereof. The second isolation layer 136 may be made of or include silicon oxide, carbon-containing silicon oxide, another suitable material, or a combination thereof.

In some embodiments, a first isolation material layer and a second isolation material layer are sequentially deposited to overfill the trench 124A. The first isolation material layer may be deposited using a CVD process, an ALD process, another applicable process, or a combination thereof. The second isolation material layer may be deposited using a CVD process, an ALD process, an FCVD process, another applicable process, or a combination thereof. Afterwards, a planarization process is used to remove the portions of the first isolation material layer and the second isolation material layer that are outside of the trench 124A. The planarization process may be a CMP process. As a result, the remaining portion of the first isolation material layer forms the first isolation layer 134 of the isolation structure 138. The remaining portion of the second isolation material layer forms the second isolation layer 136 of the isolation structure 138.

As shown in FIG. 1K, the upper portion of the isolation structure 138 is removed, in accordance with some embodiments. As a result, a trench 124A′ is formed. The trench 124A′ exposes multiple parts of the semiconductor layer 104. The exposed parts of the semiconductor layer 104 may be used to form multiple channel structures later.

FIGS. 1K-1 to 1R-1 are cross-sectional views of a process for forming a portion of a semiconductor device structure, in accordance with some embodiments. In some embodiments, FIG. 1K-1 is a cross-sectional view taken along the imaginary plane P in FIG. 1K. As shown in FIGS. 1K and 1K-1, the trench 124A′ exposes the edges of multiple parts of the semiconductor layer 104. The trench 124A′ also exposes the edges of the protective spacers 118A and the isolation feature 120.

As shown in FIGS. 1L and 1L-1, the multiple parts of the semiconductor layer 104 are partially removed, in accordance with some embodiments. As a result, the edges of the multiple parts of the semiconductor layer 104 retreat from the edges of the protective spacers 118A, so as to form multiple recesses 140. The recesses 140 may create more space for metal gate stacks that will be formed later. In some embodiments, multiple parts of the semiconductor layer 104 are laterally etched. The multiple parts of the semiconductor layer 104 are may be laterally etched using a wet etching process, a dry etching process, or a combination thereof. In some other embodiments, the multiple parts of the semiconductor layer 104 are partially oxidized before being laterally etched.

As shown in FIGS. 1M and 1M-1, the protective spacers 118A are removed, in accordance with some embodiments. As a result, multiple parts of the semiconductor layer 104 are released. Multiple semiconductor nanostructures 104′ are formed, as shown in FIGS. 1M and 1M-1. The semiconductor nanostructures 104′ may function as channel structures. In some embodiments, each of the semiconductor nanostructures 104′ has one end that is adjacent to the insulating wall 128. The ends of the semiconductor nanostructures 104′ may be in direct contact with the first insulating layer 126a of the insulating wall 128.

In some embodiments, the protective spacers 118A are removed using an etching process. During the etching process, the nearby elements such as the semiconductor layer 104, the isolation feature 120, and the insulating wall 128 are also partially removed. As a result, recesses 140′ are formed. The recesses 140′ connect the trench 124A′.

As shown in FIG. 1M-1, the first insulating layer 126a is partially removed to form recesses that expose the second insulating layer 126b. The first insulating layer 126a may be partially etched by the etching process for removing the protected spacers 118A. In some other embodiments, another etching process is performed to form the recesses exposing the second insulating layer 126b.

In some embodiments, the first insulating layer 126a is laterally etched. As a result, each of the recesses extends laterally towards the center of the end of the respective semiconductor nanostructure 104′. Each of the recesses is thus wider than a distance between the isolation feature 120 and the semiconductor nanostructure 104′, as shown in FIG. 1M-1.

As shown in FIGS. 1N and 1N-1, multiple metal gate stacks 148 are formed to surround intermediate portions of the semiconductor nanostructures 104′, in accordance with some embodiments. The metal gate stacks 148 are formed to fill the recesses 140′, in accordance with some embodiments. As a result, the metal gate stacks 148 are wrapped around the semiconductor nanostructures 104′.

In some embodiments, due to the lateral etch of the first insulating layer 126a, each of the metal gate stacks 148 may laterally extend along the insulating layer 126b towards the center of the end of the respective semiconductor nanostructures 104′. As a result, more area of the semiconductor nanostructure 104′ is wrapped around by the metal gate stack 148. The short channel effect (SCE) control may thus be improved.

Each of the metal gate stacks 148 includes multiple metal gate stack layers. Each of the metal gate stacks 148 may include a gate dielectric layer 144 and a metal gate electrode 146. The metal gate electrode 146 may include one or more work function layers. In some embodiments, the formation of the metal gate stacks 148 involves the deposition of multiple metal gate stack layers to fill the recesses 140′.

In some embodiments, the gate dielectric layer 144 is made of or includes a dielectric material with high dielectric constant (high-K). The gate dielectric layer 144 may be made of or include hafnium oxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, one or more other suitable high-K materials, or a combination thereof. The gate dielectric layer 144 may be deposited using an ALD process, a CVD process, one or more other applicable processes, or a combination thereof. The formation of the gate dielectric layer 144 may further involve one or more thermal operations.

In some embodiments, before the formation of the gate dielectric layer 144, interfacial layers 142 are formed on the surfaces of the semiconductor nanostructures 104′. The interfacial layers 142 are very thin and are made of silicon oxide or germanium oxide, for example. The interfacial layers 142 may be formed by oxidizing portions of the semiconductor nanostructures 104′.

The work function layer of the metal gate electrode 146 may be used to provide the desired work function for transistors to enhance device performance including improved threshold voltage. In some embodiments, the work function layer is used for forming a PMOS device. The work function layer is a p-type work function layer. The p-type work function layer is capable of providing a work function value that is suitable for the device, which may be equal to or greater than about 4.8 eV.

The p-type work function layer may include metal, metal carbide, metal nitride, one or more other suitable materials, or a combination thereof. For example, the p-type metal includes tantalum nitride, tungsten nitride, titanium, titanium nitride, one or more other suitable materials, or a combination thereof.

In some embodiments, the work function layer is used for forming an NMOS device. The work function layer is an n-type work function layer. The n-type work function layer is capable of providing a work function value that is suitable for the device, which may be equal to or less than about 4.5 eV.

The n-type work function layer may include metal, metal carbide, metal nitride, or a combination thereof. For example, the n-type work function layer includes titanium nitride, tantalum, tantalum nitride, one or more other suitable materials, or a combination thereof. In some embodiments, the n-type work function is an aluminum-containing layer. The aluminum-containing layer may be made of or include TiAlC, TiAlO, TiAlN, one or more other suitable materials, or a combination thereof.

The work function layer may also be made of or include hafnium, zirconium, titanium, tantalum, aluminum, metal carbides (e.g., hafnium carbide, zirconium carbide, titanium carbide, aluminum carbide), aluminides, ruthenium, palladium, platinum, cobalt, nickel, conductive metal oxides, or a combinations thereof. The thickness and/or the compositions of the work function layer may be fine-tuned to adjust the work function level.

The work function layer may be deposited over the gate dielectric layer 144 using an ALD process, a CVD process, a PVD process, an electroplating process, an electroless plating process, one or more other applicable processes, or a combination thereof. In some embodiments, one or more patterned masks are used during the formation of the work function layer. As a result, the p-type work function layer and the n-type work function layer are selectively formed over respective regions.

In some embodiments, a barrier layer is formed before the work function layer to interface the gate dielectric layer 144 with the subsequently formed work function layer. The barrier layer may also be used to prevent diffusion between the gate dielectric layer 144 and the subsequently formed work function layer. The barrier layer may be made of or include a metal-containing material. The metal-containing material may include titanium nitride, tantalum nitride, one or more other suitable materials, or a combination thereof. The barrier layer may be deposited using an ALD process, a CVD process, a PVD process, an electroplating process, an electroless plating process, one or more other applicable processes, or a combination thereof.

Afterwards, an etching process is performed to remove the portions of the metal gate electrodes 146 that are outside of the recesses 140′, in accordance with some embodiments. In some embodiments, portions of the gate dielectric layer 144 extend outside of the recesses 140′. The portions of the gate dielectric layer 144 further extend along the sidewalls of the trench 124A′ and extend over elements that are outside of the trench 124A′, as shown in FIG. 1N.

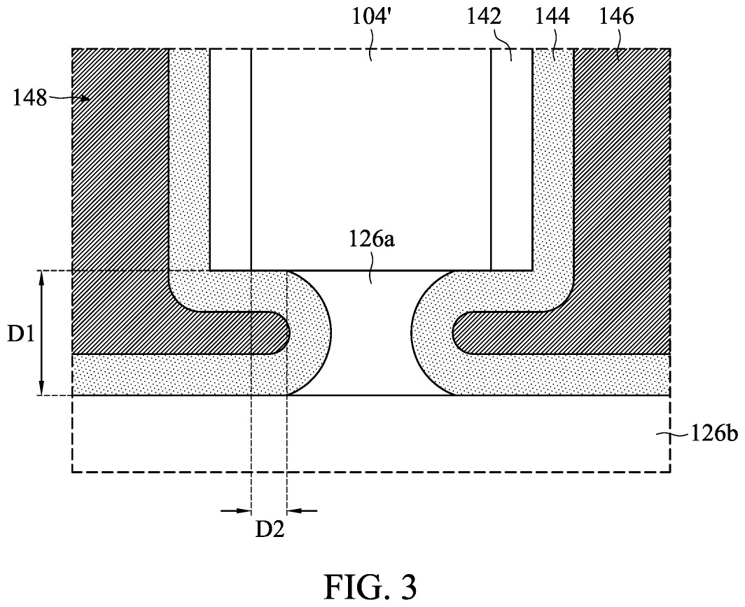

FIG. 3 is a cross-sectional view of a portion of a semiconductor device structure, in accordance with some embodiments. In some embodiments, FIG. 3 is an enlarged view showing a portion of the structure shown in FIG. 1N-1. In some embodiments, the lateral etch of the first insulating layer 126a is carefully tuned, which allows the metal gate stack 148 laterally extends closer to the center of the end of the semiconductor nanostructure 104′. The short channel effect (SCE) control may thus be improved further.

As shown in FIG. 3, the metal gate stack 148 has a first extension portion and a second extension portion. In some embodiments, the first extension portion and the second extension portion laterally extend towards each other along the end of the semiconductor nanostructure 104′. A portion of the first insulating layer 126a is between the first extension portion and the second extension portion. As shown in FIG. 3, each of the first extension portion and the second extension portion has a vertical distance D1 and a lateral distance D2. The distance D1 may be within a range from about 1 nm to about 5 nm, and the distance D2 may be within a range from about 1 nm to about 3 nm.

However, embodiments of the disclosure are not limited thereto. In some other embodiments, the insulating wall 128 is substantially not removed or not laterally removed. In these embodiments, the distances D1 and/or D2 are substantially equal to zero.

As shown in FIGS. 1O and 1O-1, a dielectric structure 154 is formed over the gate dielectric layer 144 to fill the trench 124A′, in accordance with some embodiments. In some embodiments, the dielectric structure 154 includes a first dielectric layer 150 and a second dielectric layer 152. The first dielectric layer 150 may be made of or include silicon nitride, silicon oxynitride, another suitable material, or a combination thereof. The second dielectric layer 152 may be made of or include silicon oxide, carbon-containing silicon oxide, another suitable material, or a combination thereof.

In some embodiments, a first dielectric material layer and a second dielectric material layer are sequentially deposited to overfill the trench 124A′. The first dielectric material layer may be deposited using a CVD process, an ALD process, another applicable process, or a combination thereof. The second dielectric material layer may be deposited using a CVD process, an ALD process, an FCVD process, another applicable process, or a combination thereof.

Afterwards, a planarization process is used to remove the portions of the first dielectric material layer and the second dielectric material layer that are outside of the trench 124A′. The planarization process may be a CMP process. As a result, the remaining portion of the first dielectric material layer forms the first dielectric layer 150 of the dielectric structure 154. The remaining portion of the second dielectric material layer forms the second dielectric layer 152 of the dielectric structure 154. In some embodiments, the portion of the gate dielectric layer 144 that is outside of the trench 124A′ is also removed during the planarization process for forming the dielectric structure 154, as shown in FIG. 1O.

As shown in FIGS. 1P and 1P-1, a patterned mask 156 is formed over the structure shown in FIG. 1O, in accordance with some embodiments. Afterwards, with the patterned mask 156 as an etching mask, the dielectric layer 152 of the dielectric structure 154 is partially removed, as shown in FIGS. 1P and 1P-1 in accordance with some embodiments. As a result, openings 158 are formed.

As shown in FIGS. 1Q and 1Q-1, the dielectric layer 150 of the dielectric structure 154 is then partially removed, in accordance with some embodiments. As a result, the openings 158 expose the gate dielectric layer 144 and the metal gate electrodes 146. As shown in FIG. 1Q-1, each of the openings 158 exposes two nearby metal gate stacks 148.

As shown in FIGS. 1R and 1R-1, conductive structures 160 are formed in the openings 158, in accordance with some embodiments. The conductive structure 160 is electrically connected to the nearby metal gate stacks 148. As a result, the metal gate stacks 148 originally exposed by the opening 158 are electrically connected to each other through the conductive structure 160. In some embodiments, each of the conductive structures 160 is in direct contact with the nearby metal gate stacks 148.

In some embodiments, the conductive structures 160 are made of or include tungsten, ruthenium, cobalt, molybdenum, another suitable material, or a combination thereof. In some embodiments, a conductive material layer is deposited to fill the openings 158. The conductive material layer may be deposited using a CVD process, an ALD process, an electroless plating process, an electroplating process, another applicable process, or a combination thereof. Afterwards, one or more etching back processes are used to partially remove the conductive material layer and the gate dielectric layer 144. As a result, the remaining portions of the conductive material layer form the conductive structures 160.

As show in FIG. 1S, protective caps 162 are formed over the conductive structures 160 to fill the openings 158, in accordance with some embodiments. The protective caps 162 may be made of or include silicon nitride, silicon oxynitride, carbon-containing silicon nitride, carbon-containing silicon oxynitride, carbon-containing silicon oxide, another suitable material, or a combination thereof.

In some embodiments, a protective material layer is deposited to overfill the openings 158. The protective material layer may be a single layer. Alternatively, the protective material layer includes multiple sub-layers. Afterwards, a planarization process is used to remove the portion of the protective material layer that is outside of the openings 158. As a result, the remaining portions of the protective material layer form the protective caps 162.

As shown in FIG. 1T, the mask layers 106 are removed to form openings 164, in accordance with some embodiments. The openings 164 expose the semiconductor layer 102b that function as sacrificial layer.

Afterwards, the semiconductor layer 102b is removed. As a result, the tops of the semiconductor nanostructures 104′ are exposed. Then, epitaxial structures 168 are formed over the tops of the semiconductor nanostructures 104′, as shown in FIG. 1U in accordance with some embodiments. The epitaxial structures 168 may function as source/drain structures. In some embodiments, the epitaxial structures 168 are drain structures. In some other embodiments, the epitaxial structures 168 are source structures.

In some embodiments, before the formation of the epitaxial structures 168, lightly doped epitaxial structures 166 are formed on the tops of the semiconductor nanostructures 104′. The lightly doped epitaxial structures 166 may function as lightly doped source/drain (LDS/D) structures. In some embodiments, the dopant concentration of the epitaxial structures 168 is greater than the dopant concentration of the lightly doped epitaxial structures 166.

In some embodiments, the epitaxial structures 168 are designed to function as source/drain structures of p-channel field-effect transistors (PFET). The epitaxial structures 168 may include epitaxially grown silicon germanium (SiGe), epitaxially grown silicon, or another suitable epitaxially grown semiconductor material. In some embodiments, the epitaxial structures 168 are doped with one or more suitable p-type dopants. For example, the epitaxial structures 168 are SiGe source/drain features or Si source/drain features that are doped with boron (B), gallium (Ga), indium (In), or another suitable dopant.

In some other embodiments, the epitaxial structures 168 are designed to function as source/drain structures of n-channel field-effect transistors (NFET). The epitaxial structures 168 may include epitaxially grown silicon or another suitable epitaxially grown semiconductor material. The epitaxial structures 168 are n-type doped. In some embodiments, the epitaxial structures 168 are doped with one or more suitable n-type dopants. For example, the epitaxial structures 168 are Si source/drain features that are doped with phosphor (P), antimony (Sb), arsenic (As), or another suitable dopant.

The term “source/drain structure” may refer to a source structure or a drain structure, individually or collectively, depending on the context.

In some embodiments, the lightly doped epitaxial structures 166 and the epitaxial structures 168 are formed using multiple epitaxial growth operations. In some embodiments, these epitaxial growth operations are performed in-situ in the same process chamber. In some embodiments, the vacuum of the process chamber is not broken before the formation of the lightly doped epitaxial structures 166 and the epitaxial structures 168 is accomplished. The reaction gases may be varied in the reaction chamber during the epitaxial growth operations.

These epitaxial growth operations may be achieved using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, one or more other applicable processes, or a combination thereof.

In some embodiments, the epitaxial structures 168 are doped in-situ during their epitaxial growth. The initial reaction gas mixture for forming the epitaxial structures 168 contains respective dopants. In some embodiments, the epitaxial structures 168 are further exposed to one or more annealing processes to activate the dopants. For example, a rapid thermal annealing process is used.

Afterwards, metal-semiconductor compound elements 170 and conductive pads 172 are formed over the epitaxial structures 168, as shown in FIG. 1U in accordance with some embodiments. In some embodiments, the tops of the conductive pads 172 are substantially level with the tops of the protective caps 162. The conductive pads 172 may be made of or include cobalt, tungsten, ruthenium, one or more other suitable materials, or a combination thereof. The metal-semiconductor compound elements 170 may be made of or include titanium silicide, nickel silicide, cobalt silicide, titanium silicon germanium, one or more other suitable materials, or a combination thereof.

The formation of the metal-semiconductor compound elements 170 and the conductive pads 172 may involve one or more patterning processes, one or more deposition processes, one or more annealing processes, and one or more planarization processes.

As shown in FIG. 1V, second conductive structures 174 are formed penetrating through the protective caps 162, in accordance with some embodiments. In some embodiments, each of the second conductive structures 174 is electrically connected to the conductive structure 160 thereunder.

In some embodiments, the protective caps 162 are partially removed to form openings that expose the conductive structures 160 under the protective caps 162. Afterwards, a conductive material layer is deposited to overfill the openings. The conductive material layer may be made of or include tungsten, ruthenium, cobalt, molybdenum, another suitable material, or a combination thereof. The conductive material layer may be deposited using a CVD process, an ALD process, an electroless plating process, an electroplating process, another applicable process, or a combination thereof. Afterwards, a planarization process is used to remove the portion of the conductive material layer that is outside of the openings. As a result, the remaining portions of the conductive material layer form the second conductive structures 174.

As shown in FIG. 1W, an etch stop layer 176 and a dielectric layer 178 are deposited, in accordance with some embodiments. Afterwards, the etch stop layer 176 and the dielectric layer 178 are patterned to form openings that expose the conductive pads 172. Afterwards, conductive contacts 180 are formed in the openings. Each of the conductive contacts 180 may form electrical connection between multiple epitaxial structures 168 through the conductive pads 172.

Afterwards, an etch stop layer 182 and a dielectric layer 184 are formed, as shown in FIG. 1W in accordance with some embodiments. The etch stop layer 182 and the dielectric layer 184 may then be patterned to form multiple via holes. Afterwards, multiple gate conductive vias 186G are formed in some of the via holes, and multiple conductive vias 186D (such as drain conductive vias or source conductive vias) are formed in some of the via holes. Each of the gate conductive vias 186G may be electrically connected to the second conductive structure 174 thereunder. Each of the conductive vias 186D may be electrically connected to the conductive contact 180 thereunder.

As shown in FIG. 1X, the semiconductor substrate 100 and the semiconductor fins 101 are removed to form openings 188, in accordance with some embodiments. The openings 188 expose the semiconductor layer 102a that function as sacrificial layer.

Afterwards, the semiconductor layer 102a is removed. As a result, the bottoms of the semiconductor nanostructures 104′ are exposed.

As shown in FIG. 1Y, epitaxial structures 192 are formed below the bottoms of the semiconductor nanostructures 104′, in accordance with some embodiments. The epitaxial structures 192 may function as source/drain structures. In some embodiments, the epitaxial structures 192 are source structures. In some other embodiments, the epitaxial structures 192 are drain structures.

In some embodiments, before the formation of the epitaxial structures 192, lightly doped epitaxial structures 190 are formed below the bottoms of the semiconductor nanostructures 104′. The lightly doped epitaxial structures 190 may function as lightly doped source/drain (LDS/D) structures. In some embodiments, the dopant concentration of the epitaxial structures 192 is greater than the dopant concentration of the lightly doped epitaxial structures 190.

In some embodiments, the epitaxial structures 192 are designed to function as source/drain structures of p-channel field-effect transistors (PFET). The epitaxial structures 192 may include epitaxially grown silicon germanium (SiGe), epitaxially grown silicon, or another suitable epitaxially grown semiconductor material. In some embodiments, the epitaxial structures 192 are doped with one or more suitable p-type dopants. For example, the epitaxial structures 192 are SiGe source/drain features or Si source/drain features that are doped with boron (B), gallium (Ga), indium (In), or another suitable dopant.

In some other embodiments, the epitaxial structures 192 are designed to function as source/drain structures of n-channel field-effect transistors (NFET). The epitaxial structures 192 may include epitaxially grown silicon or another suitable epitaxially grown semiconductor material. The epitaxial structures 192 are n-type doped. In some embodiments, the epitaxial structures 192 are doped with one or more suitable n-type dopants. For example, the epitaxial structures 192 are Si source/drain features that are doped with phosphor (P), antimony (Sb), arsenic (As), or another suitable dopant.

The term “source/drain structure” may refer to a source structure or a drain structure, individually or collectively, depending on the context.

In some embodiments, the lightly doped epitaxial structures 190 and the epitaxial structures 192 are formed using multiple epitaxial growth operations. In some embodiments, these epitaxial growth operations are performed in-situ in the same process chamber. In some embodiments, the vacuum of the process chamber is not broken before the formation of the lightly doped epitaxial structures 190 and the epitaxial structures 192 is accomplished. The reaction gases may be varied in the reaction chamber during the epitaxial growth operations.

These epitaxial growth operations may be achieved using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, one or more other applicable processes, or a combination thereof.

In some embodiments, the epitaxial structures 192 are doped in-situ during their epitaxial growth. The initial reaction gas mixture for forming the epitaxial structures 192 contains respective dopants. In some embodiments, the epitaxial structures 192 are further exposed to one or more annealing processes to activate the dopants. For example, a rapid thermal annealing process is used.

Afterwards, metal-semiconductor compound elements 194 and conductive pads 196 are formed over the epitaxial structures 192, as shown in FIG. 1Y in accordance with some embodiments. The conductive pads 196 may be made of or include cobalt, tungsten, ruthenium, one or more other suitable materials, or a combination thereof. The metal-semiconductor compound elements 194 may be made of or include titanium silicide, nickel silicide, cobalt silicide, titanium silicon germanium, one or more other suitable materials, or a combination thereof.

The formation of the metal-semiconductor compound elements 194 and the conductive pads 196 may involve one or more patterning processes, one or more deposition processes, one or more annealing processes, and one or more planarization processes.

Afterwards, similar to the embodiments illustrated in FIG. 1W, multiple dielectric layers and multiple conductive structures such as conductive contacts and conductive vias may be formed below the structure shown in FIG. 1Y.

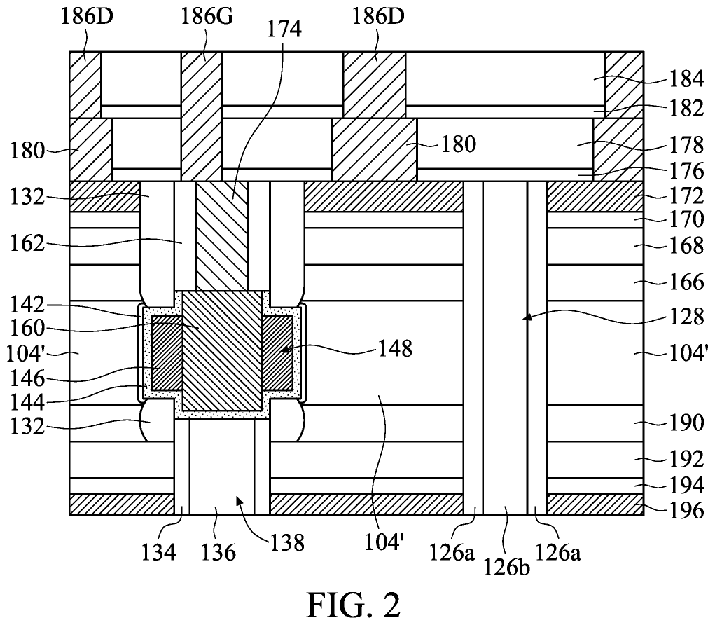

FIG. 2 is a cross-sectional view of a portion of a semiconductor device structure, in accordance with some embodiments. In some embodiments, FIG. 2 is a cross-sectional view of a portion of the structure shown in FIG. 1Y. As shown in FIG. 2, the conductive structure 160 electrically connects the metal gate stacks 148 that are nearby. The conductive structure 160 is electrically connected to the gate conductive via 186G through the second conductive structure 174. In some embodiments, the insulating wall 128 is in direct contact with the semiconductor nanostructures 104′, the epitaxial structures 168 and 192, the metal-semiconductor compound elements 170 and 194, and the conductive pads 172 and 196.

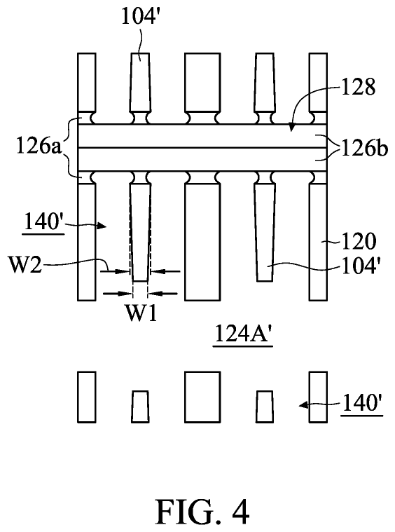

FIG. 4 is a cross-sectional view of a portion of a semiconductor device structure, in accordance with some embodiments. In some embodiments, FIG. 4 shows a structure that is similar to the embodiments shown in FIG. 1M-1. In some embodiments, the etching process for removing the protective spacers 118A is fine-tuned. As a result, the semiconductor nanostructures 104′ in FIG. 4 may have a profile that is different than the structure shown in FIG. 1M-1.

In some embodiments, each of the semiconductor nanostructures 104′ has an inclined sidewall. In some embodiments, each of the semiconductor nanostructures 104′ gradually becomes narrower along a direction away from the ends of the semiconductor nanostructures 104′ that connect the insulating wall 128. As shown in FIG. 4, each of the semiconductor nanostructures 104′ has a first width W1 and a second width W2. The second width W2 is the width of the end that connects the insulating wall 128. The first width W1 is the width of the opposite end of the semiconductor nanostructure 104′.

The first width W1 of the semiconductor nanostructure 104′ may be within a range from about 4 nm to about 7 nm. The second width W2 of the semiconductor nanostructure 104′ may be within a range from about 5 nm to about 8 nm. The difference between the first width W1 and the second width W2 may be within a range from about 0.5 nm to about 1 nm.

Embodiments of the disclosure form a semiconductor device structure with vertical gate all around (VGAA) feature. An insulating wall is formed adjacent to the semiconductor layer that is used for forming channel structures. With the assist of the insulating wall, a metal gate stack may be formed to wrap the channel structure in a better manner. The short channel effect control may thus be improved. The performance and reliability of the semiconductor device structure are significantly improved.

In accordance with some embodiments, a semiconductor device structure is provided. The semiconductor device structure includes a channel structure and a metal gate stack laterally surrounding an intermediate portion of the channel structure. The semiconductor device structure also includes a first epitaxial structure above the channel structure and the metal gate stack. The semiconductor device structure further includes a second epitaxial structure below the channel structure and the metal gate stack. In addition, the semiconductor device structure includes an insulating wall adjacent to the channel structure, and the metal gate stack extends into the insulating wall.

In accordance with some embodiments, a method for forming a semiconductor device structure is provided. The method includes forming a channel structure over a substrate and forming a protective spacer over sidewalls of the channel structure. The method also includes forming an insulating wall adjacent to an end of the channel structure. The method further includes removing the protective spacer to expose the channel structure. In addition, the method includes forming a metal gate stack surrounding an intermediate portion of the channel structure.

In accordance with some embodiments, a method for forming a semiconductor device structure is provided. The method includes forming a fin structure over a substrate. The fin structure has a first sacrificial layer, a channel layer, and a second sacrificial layer. The channel layer is between the first sacrificial layer and the second sacrificial layer. The method also includes forming an isolation feature laterally surrounding the fin structure and partially removing the fin structure and the isolation feature to form a first trench and a second trench. The method further includes forming an insulating wall in the second trench and forming an isolation structure in the first trench. In addition, the method includes recessing the isolation structure to expose the channel layer and partially removing the channel layer to form a semiconductor nanostructure. The method also includes forming a metal gate stack surrounding the semiconductor nanostructure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device structure, comprising:
a channel structure;
a metal gate stack laterally surrounding an intermediate portion of the channel structure;
a first epitaxial structure above the channel structure and the metal gate stack;
a second epitaxial structure below the channel structure and the metal gate stack; and
an insulating wall adjacent to the channel structure, wherein the metal gate stack extends into the insulating wall.

2. The semiconductor device structure as claimed in claim 1, wherein the insulating wall has a first insulating layer and a second insulating layer, the first insulating layer surrounds the second insulating layer, the first insulating layer and the second insulating layer are made of different materials, and the metal gate stack penetrates through the first insulating layer and reaches the second insulating layer.

3. The semiconductor device structure as claimed in claim 2, wherein the metal gate stack has a first extension portion and a second extension portion, and the first extension portion and the second extension portion laterally extend towards each other along an end of the channel structure.

4. The semiconductor device structure as claimed in claim 3, wherein a portion of the first insulating layer is between the first extension portion and the second extension portion.

5. The semiconductor device structure as claimed in claim 1, further comprising:
a second channel structure;
a second metal gate stack laterally surrounding a second intermediate portion of the second channel structure; and
a conductive structure between the metal gate stack and the second metal gate stack, wherein the conductive structure electrically connects the metal gate stack and the second metal gate stack.

6. A method for forming a semiconductor device structure, comprising:
forming a channel structure over a substrate;
forming a protective spacer over sidewalls of the channel structure;
forming an insulating wall adjacent to an end of the channel structure;
removing the protective spacer to expose the channel structure; and
forming a metal gate stack surrounding an intermediate portion of the channel structure.

7. The method for forming a semiconductor device structure as claimed in claim 6, further comprising:
partially removing the insulating wall after the removing of the protective spacer and before the formation of the metal gate stack.

8. The method for forming a semiconductor device structure as claimed in claim 7, wherein the insulating wall has a first insulating layer and a second insulating layer, the first insulating layer surrounds the second insulating layer, and the first insulating layer and the second insulating layer are made of different materials.

9. The method for forming a semiconductor device structure as claimed in claim 8, wherein the partial removal of the insulating wall comprises:
partially removing the first insulating layer to form a recess exposing the second insulating layer.

10. The method for forming a semiconductor device structure as claimed in claim 9, further comprising:
laterally etching the first insulating layer so that the recess extends laterally towards a center of the end of the channel structure.

11. The method for forming a semiconductor device structure as claimed in claim 6, further comprising:
exposing a top of the channel structure;
forming a first epitaxial structure over the top of the channel structure;
removing the substrate after the formation of the first epitaxial structure;
exposing a bottom of the channel structure; and
forming a second epitaxial structure below the bottom of the channel structure.

12. The method for forming a semiconductor device structure as claimed in claim 6, further comprising:
forming a second channel structure over the substrate;
forming a second metal gate stack surrounding the second channel structure; and
forming a conductive structure between the metal gate stack and the second metal gate stack, wherein the conductive structure electrically connects the metal gate stack and the second metal gate stack.

13. The method for forming a semiconductor device structure as claimed in claim 12, further comprising:
forming an isolation structure, wherein a portion of the isolation structure is between the channel structure and the second channel structure;
removing an upper portion of the isolation structure so that the channel structure and the second channel structures are exposed;
forming the metal gate stack and the second metal gate stack surrounding the channel structure and the second channel structure, respectively;
forming a dielectric layer over the isolation structure to cover the metal gate stack and the second metal gate stack;
partially removing the dielectric layer to form an opening partially exposing the metal gate stack and the second metal gate stack; and
forming the conductive structure in the opening, wherein the conductive structure is in direct contact with the metal gate stack and the second metal gate stack.

14. The method for forming a semiconductor device structure as claimed in claim 13, further comprising:
forming a second conductive structure over the conductive structure; and
forming a gate conductive via over the second conductive structure.

15. The method for forming a semiconductor device structure as claimed in claim 14, further comprising:
forming a protective cap over the conductive structure, wherein a top of the protective cap is substantially level with a top of the dielectric layer;
exposing a top of the channel structure after the protective cap is formed;
forming an epitaxial structure over the top of the channel structure; and
forming the second conductive structure in the protective cap after the epitaxial structure is formed, wherein the second conductive structure is electrically connected to the conductive structure.

16. A method for forming a semiconductor device structure, comprising:
forming a fin structure over a substrate, wherein the fin structure has a first sacrificial layer, a channel layer, and a second sacrificial layer, and the channel layer is between the first sacrificial layer and the second sacrificial layer;
forming an isolation feature laterally surrounding the fin structure;
partially removing the fin structure and the isolation feature to form a first trench and a second trench;
forming an insulating wall in the second trench;
forming an isolation structure in the first trench;
recessing the isolation structure to expose the channel layer;
partially removing the channel layer to form a semiconductor nanostructure; and
forming a metal gate stack surrounding the semiconductor nanostructure.

17. The method for forming a semiconductor device structure as claimed in claim 16, further comprising:
forming protective spacers on sidewalls of the channel layer; and
removing the protective spacers after the recessing of the isolation structure and before the partial removal of the channel layer.

18. The method for forming a semiconductor device structure as claimed in claim 17, further comprising:
partially removing the insulating wall after the removal of the protective spacers and before the formation of the metal gate stack.

19. The method for forming a semiconductor device structure as claimed in claim 16, further comprising:
removing the second sacrificial layer to expose a top of the semiconductor nanostructure;
forming a first epitaxial structure over the top of the semiconductor nanostructure;
removing the substrate;
removing the first sacrificial layer to expose a bottom of the semiconductor nanostructure; and
forming a second epitaxial structure below the bottom of the semiconductor nanostructure.

20. The method for forming a semiconductor device structure as claimed in claim 16, further comprising
forming a dielectric layer over the isolation structure to cover the metal gate stack;
partially removing the dielectric layer to form an opening exposing the metal gate stack; and
forming a conductive structure in the opening, wherein the conductive structure is electrically connected to the metal gate stack.
